(19) United States
(12) Patent Application Publication
(10) Pub. No.: US 2025/0218891 A1
(43) Pub. Date: Jul. 3, 2025

(54) INTEGRATED CIRCUIT (IC) STRUCTURES WITH THERMAL PATH TO CARRIER SUBSTRATE

(71) Applicant: Taiwan Semiconductor Manufacturing Company, Ltd., Hsin-Chu (TW)

(72) Inventors: Yung-Shih Cheng, Hsinchu City (TW); Wen-Sheh Huang, Hsinchu City (TW)

(21) Appl. No.: 18/403,148

(22) Filed: Jan. 3, 2024

(51) Int. Cl. H01L 23/373; H01L 23/00; H01L 23/522; H01L 23/528

(52) U.S. Cl. CPC H01L 23/3738; H01L 23/5226; H01L 23/528; H01L 24/03; H01L 24/05; H01L 24/08; H01L 24/80; H01L 2224/034; H01L 2224/0383; H01L 2224/05686; H01L 2224/08225; H01L 2224/80895; H01L 2224/80896; H01L 2924/13081

(57) ABSTRACT

A semiconductor structure includes a device layer having a transistor device and a PN junction structure coupled to the transistor device. The PN junction structure includes a first doped region and a second doped region, and the first doped region is electrically connected to a gate stack of the transistor device. The semiconductor structure includes a frontside interconnect structure over a frontside of the device layer, the frontside interconnect structure includes thermal path metal features electrically connected to the second doped region of the PN junction structure. The semiconductor structure includes a bonding oxide layer over the frontside interconnect structure, the bonding oxide layer embeds a thermal path metal contact electrically connected to the thermal path metal features. The semiconductor structure includes a carrier substrate over the bonding oxide layer, the carrier substrate landing on a top surface of the thermal path metal contact.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, signal and power connections may be routed to a backside of a circuit structure for power and chip space optimization. In these scenarios, after forming frontside IC features over a device substrate, the circuit structure may be attached to a carrier substrate through oxide bonding. Then, the circuit structure is thinned down from a backside to partially or fully remove the device substrate, and backside interconnect features such as backside vias, backside metal lines, and backside power rails are formed on the backside of the thinned down circuit structure. However, device self-heating becomes an issue due to the device substrate being partially or fully removed. The device substrate previously provided a thermal path to absorb heat generated from the transistor devices. With it removed, heat is trapped such that the transistor devices may have risk of damage due to self-heating.

Therefore, although existing IC structures having backside features for signal and power connections have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a semiconductor structure having a thermal conductive path from a transistor device to a carrier substrate, according to an embodiment of the present disclosure.

FIG. 2 illustrates a flow chart of a method to form a semiconductor structure having a thermal conductive path from a transistor device to a carrier substrate, in portion or in entirety, according to an embodiment of the present disclosure.

FIGS. 3-9 illustrate a semiconductor structure having a thermal conductive path from a transistor device to a carrier substrate at intermediate stages of fabrication and processed in accordance with the method of FIG. 2, according to an embodiment of the present disclosure.

FIG. 10A illustrates a top view of a semiconductor structure having multiple thermal conductive paths from multiple transistor devices to a carrier substrate, according to an embodiment of the present disclosure.

FIG. 10B-1 illustrates a cross-sectional view of a semiconductor structure cut along the lines B-B′ in FIG. 10A, according to an embodiment of the present disclosure.

FIG. 10B-2 illustrates the mechanism of releasing heat from a transistor device according to the semiconductor structure of FIG. 10B-1.

FIG. 10C illustrates a cross-sectional view of a semiconductor structure cut along the lines C-C′ in FIG. 10A, according to an embodiment of the present disclosure.

FIGS. 11A-11C illustrates metal line and metal via dimensions for thermal conductive paths and for functional circuit paths, according to various embodiments of the present disclosure.

FIG. 12 illustrates a circuit diagram of multiple transistor devices with their gates coupled to a carrier substrate.

FIG. 13 illustrates the bonding between a device wafer to a carrier wafer, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. For These are, of course, merely examples and are not intended to be limiting. example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximately,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, can be understood to be within +/−10% between the compared features. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to semiconductor structures having thermal paths for dissipating heat generated by transistor devices. Specifically, the present disclosure describes creating thermal conductive paths routing from gate terminals of transistor devices to the carrier substrate, thereby relaxing unwanted thermal effect by having the carrier substrate absorb dissipated heat. The thermal path is made possible by patterning the bonding oxides between the carrier wafer and the device wafer such that metal contacts penetrate through the bonding oxides to electrically connect between the carrier substrate and metal lines that connect to the gate terminals. Each of the thermal conductive paths include a PN junction structure coupled between a gate terminal and the metal lines that connect to the carrier substrate. The PN junction structure functions as a reverse diode that block electrical signals while allowing thermal transmission. In this way, multiple gate terminals can connect to a common carrier substrate while avoiding gate shorting issues between different gates.

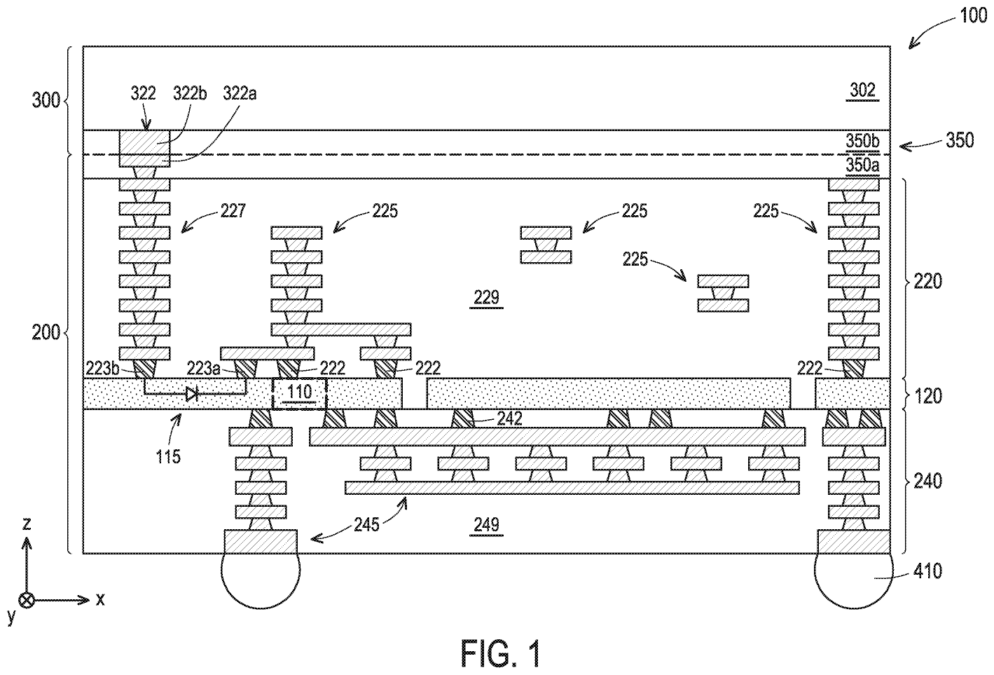

FIG. 1 illustrates a semiconductor structure 100 having a thermal conductive path from a transistor device 110 to a carrier substrate 302, according to an embodiment of the present disclosure. The transistor device 110 is shown as a dashed box for simplicity and is further described in later figures. The transistor device 110 may be one of multiple transistor devices 110 formed in a device layer 120. Each of the transistor devices 110 includes a channel region between source/drain (S/D) regions and a gate structure having a gate stack (which includes a gate electrode over a gate dielectric) over the channel region. The device layer 120 further includes a PN junction structure 115 disposed adjacent the transistor device 110. The PN junction structure 115 may be one of multiple PN junction structures 115 formed in the device layer 120. For example, additional pairs of PN junction structures 115 and transistor devices 110 may be formed in the device layer 120 in similar fashion. The PN junction structure 115 is shown as a reverse diode having a first terminal and a second terminal. The PN junction structure 115 will be further described in later figures.

Still referring to FIG. 1, an interconnect structure 220 is formed over a frontside of the device layer 120. The interconnect structure 220 electrically couple various devices (for example, p-type transistor devices 110 and/or n-type transistor devices 110, other transistors, resistors, capacitors, and/or inductors) and/or components (for example, gate stacks and/or epitaxial source/drain features of p-type transistor devices 110 and/or n-type transistor devices 110), such that the various devices and/or components can operate as specified by design requirements. The interconnect structure 220 includes a combination of dielectric layers and electrically conductive layers (e.g., metal layers) configured to form various interconnect features. The conductive layers are configured to form vertical interconnect features, such as metal vias and/or horizontal interconnect features, such as metal lines, where the metal lines are vertically disposed between metal vias. Vertical interconnect features typically connect horizontal interconnect features in different layers (or different planes) of the interconnect layer. During operation, the interconnect structure 220 is configured to route signals between the devices and/or the components of the semiconductor structure 100 and/or distribute signals (for example, clock signals, voltage signals, and/or ground signals) to the devices and/or the components of the semiconductor structure 100.

In the embodiment of FIG. 1, the interconnect structure 220 includes frontside vias such as frontside vias 222, 223a, and 223b landing on the device layer 120. The frontside vias 222 may be disposed over and electrically connected to the gate stacks and/or epitaxial source/drain features of the transistor devices 110. And the frontside vias 223a and 223b may be disposed over and electrically connected to respective first and second terminals of the PN junction structures 115. The interconnect structure 220 further includes metal features 225 disposed over and electrically connected to one or more of the frontside vias 222. The metal features 225 include metal lines vertically disposed between metal vias and may include a bottom metal line that electrically connects a frontside via 222 to a frontside via 223a (e.g., landing on top surfaces of the frontside via 222 and the frontside via 223a). The interconnect structure 220 further includes metal features 227 disposed over and electrically connected to a frontside via 223b. The metal features 227 may include a bottom metal line landing on a top surface of the frontside via 223b. The metal features 225 includes interposing metal vias and metal lines that route device signals (e.g., power lines and signal lines) to various metal layers. The metal features 227 includes interposing metal vias and metal lines that route a thermal dissipation path to the carrier substrate 302. In the present embodiment, the metal features 225 to the immediate right of the metal features 227 routes gate signals and may be referred to as gate metal features 225 or gate path metal lines 225. In the present embodiment, the metal features 227 is thermally coupled to a set of gate metal features and to a transistor device 110 through a PN junction structure 115 and may be referred to as thermal path metal features 227 or thermal path metal lines 227. The frontside vias 222, 223a, and 223b and the metal features 225 and 227 are embedded in an intermetal dielectric (IMD) structure 229 that isolates the various metal features. The frontside vias 222, 223a, and 223b, and the metal features 225 and 227 may include titanium (Ti), ruthenium (Ru), copper (Cu), nickel (Ni), cobalt (Co), tungsten (W), tantalum (Ta), or molybdenum (Mo). The IMD structure 229 may include silicon oxide, silicon oxynitride, fluorine-doped silicate glass (FSG), a low-k dielectric, combinations thereof, and/or other suitable dielectric materials.

Still referring to FIG. 1, a bonding oxide layer 350 is disposed over the interconnect structure 220, and a bonding metal contact 322 penetrates through the bonding oxide layer 350 to land on a top metal line of the metal features 227. The bonding oxide layer 350 and the bonding metal contact 322 may be formed by hybrid bonding (oxide-to-oxide and metal-to-metal). A shown, a bonding oxide layer 350a is bonded to a bonding oxide layer 350b and a bonding metal contact 322a is bonded to a bonding metal contact 322b. In the present embodiment, the bonding metal contact includes copper, and the bonding oxide layer 350a may include a via portion and a metal line portion over the via portion that is wider than the via portion. A carrier substrate 302 is disposed over the bonding oxide layer 350 and over the bonding metal contact 322. As shown, the carrier substrate 302 directly lands on and contacts a top surface of the bonding metal contact 322. The carrier substrate 302 may include silicon (Si), or other semiconductor materials such as germanium (Ge), silicon carbide (SiC), silicon germanium (SiGe), or diamond. In the present embodiment, the carrier substrate 302 is made of silicon.

Still referring to FIG. 1, an interconnect structure 240 is formed on a backside of the device layer 120 (i.e., under the device layer 120). The interconnect structure 240 electrically couple various devices (for example, p-type transistor devices 110 and/or n-type transistor devices 110, other transistors, resistors, capacitors, and/or inductors) and/or components (for example, gate stacks and/or epitaxial source/drain features of p-type transistor devices 110 and/or n-type transistor devices 110) to a backside of the device layer 120. Like the interconnect structure 220, the interconnect structure 240 includes a combination of dielectric layers and electrically conductive layers (e.g., metal layers) configured to form various interconnect features. The conductive layers are configured to form vertical interconnect features, such as metal vias and/or horizontal interconnect features, such as metal lines, where the metal lines are vertically disposed between metal vias. Vertical interconnect features typically connect horizontal interconnect features in different layers (or different planes) of the interconnect layer.

In the embodiment of FIG. 1, the interconnect structure 240 includes backside vias 242 landing on a backside of the device layer 120. The backside vias 242 may be disposed over and electrically connected to a backside of the epitaxial source/drain features of the transistor devices 110. The interconnect structure 240 further includes backside metal features 245 disposed over and electrically connected to one or more of the backside vias 242. The backside metal features 245 include metal lines vertically disposed between metal vias and may include top metal lines that electrically connect and land on a backside of the backside vias 242 and bottom metal lines that route to power and/or I/O bonding pads 410. The bonding pads 410 may be bonded to other circuit structures not shown. The backside metal features 245 includes interposing vias and metal lines that route device signals (e.g., power lines and signal lines) to various metal layers. The backside vias 242 and the backside metal features 245 are embedded in an intermetal dielectric (IMD) structure 249 that isolates the various metal features. The backside vias 242 and the backside metal features 245 may include similar materials as the frontside vias 222 and the metal features 225. The IMD structure 249 may include similar materials as the IMD structure 229.

As shown by the dashed line in FIG. 1, the semiconductor structure 100 is formed by bonding a device wafer 200 to a carrier wafer 300. The device wafer 200 and the carrier wafer 300 are bonded together through the bonding oxide layers 350a and 350b and the bonding metal contacts 322a and 322b as described above. The device wafer 200 includes the device layer 120, the interconnect structures 220 and 240, and the bonding oxide layer 350a. The carrier wafer 300 includes the carrier substrate 302 and the bonding oxide layer 350b. After the bonding, a thermal path to the carrier substrate 302 is formed for one or more transistor devices 110. For example, a thermal path propagates from a gate stack of a transistor device 110 to a frontside via 222, to metal features 225 (i.e., gate path metal lines 225), to a frontside via 223a, through a PN junction structure 115, to a frontside via 223b, to metal features 227 (i.e., thermal path metal lines), to the bonding metal contact 322, to the carrier substrate 302. As will be explained in more detail below, the PN junction structure 115 acts as a reverse diode that blocks electrical signals to prevent gate shorting while allowing thermal transmission.

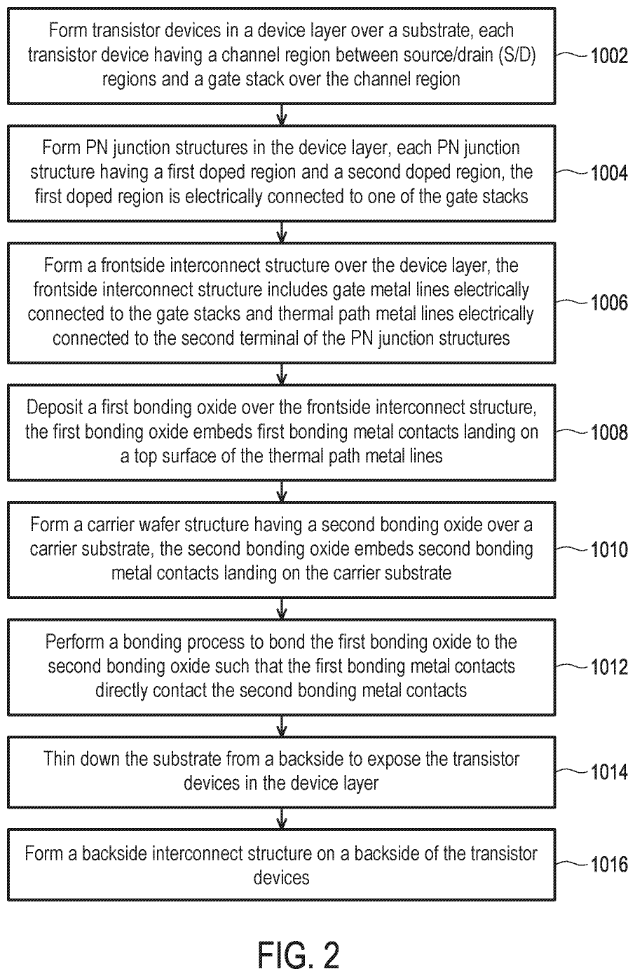

FIG. 2 illustrates a flow chart of a method 1000 to form a semiconductor structure 100 having a thermal dissipation path (like the one shown in FIG. 1), in portion or in entirety, according to an embodiment of the present disclosure. The semiconductor structure 100 corresponds to a semiconductor device, and the two terms (i.e., device and structure) may be used interchangeably. The semiconductor device may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

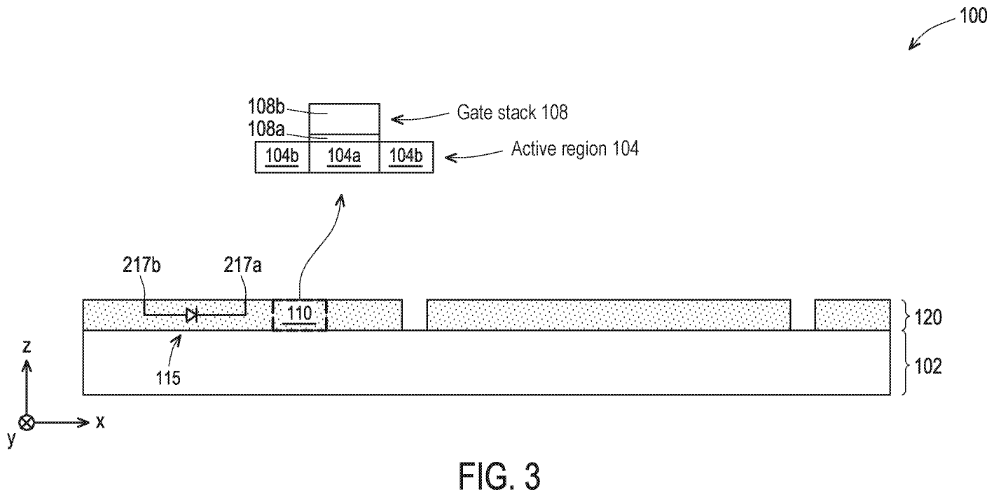

FIGS. 3-9 illustrate the formation of the semiconductor structure 100 at intermediate stages of fabrication, processed in accordance with the method 1000 of FIG. 2. Note that embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein.

Referring now to FIG. 3, the method 1000 at operation 1002 forms transistor devices 110 in a device layer 120 over a substrate 102. The substrate 102 may include silicon (Si), or other semiconductor materials such as germanium (Ge), silicon carbide (SiC), silicon germanium (SiGe), or diamond. As shown, each transistor device 110 includes an active region 104 having a channel region 104a between source/drain (S/D) regions 104b and a gate stack 108 over the channel region 104a. Each transistor device 110 may be a GAA FET device, a fin FET device, or a planar device. In the embodiment shown, the active regions 104 may be fin active regions 104 that protrude from the substrate 102 to above an isolation structure. The fin active regions 104 form the active regions 104 for GAA or fin FET devices.

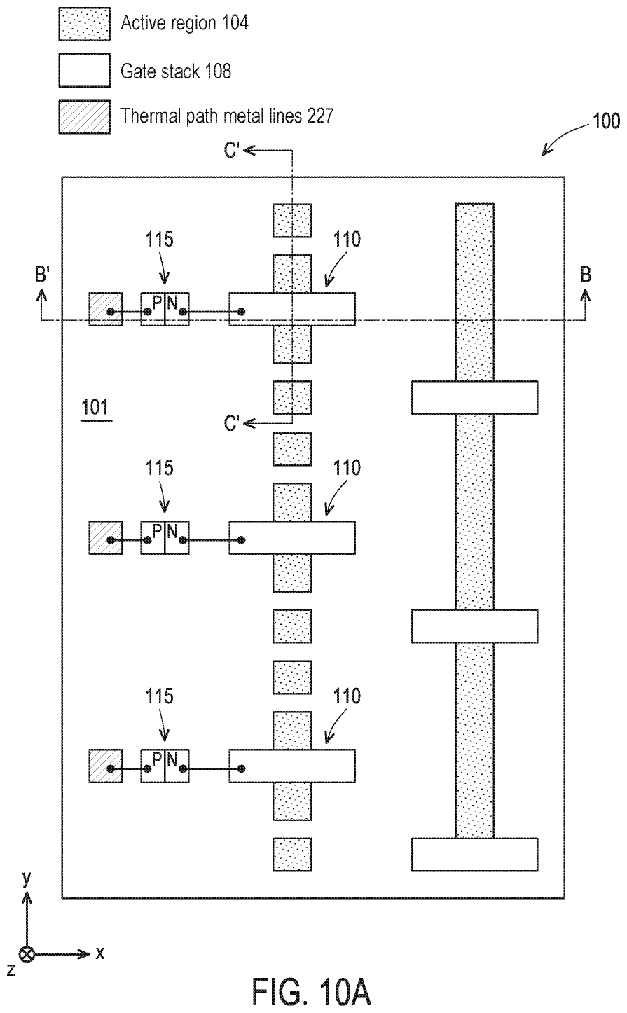

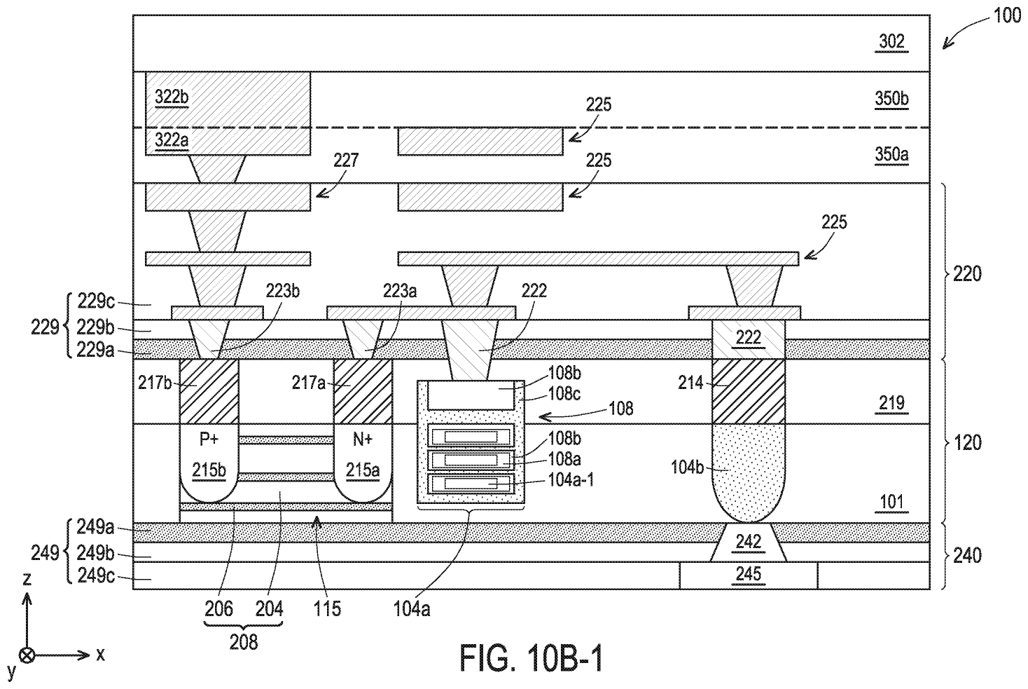

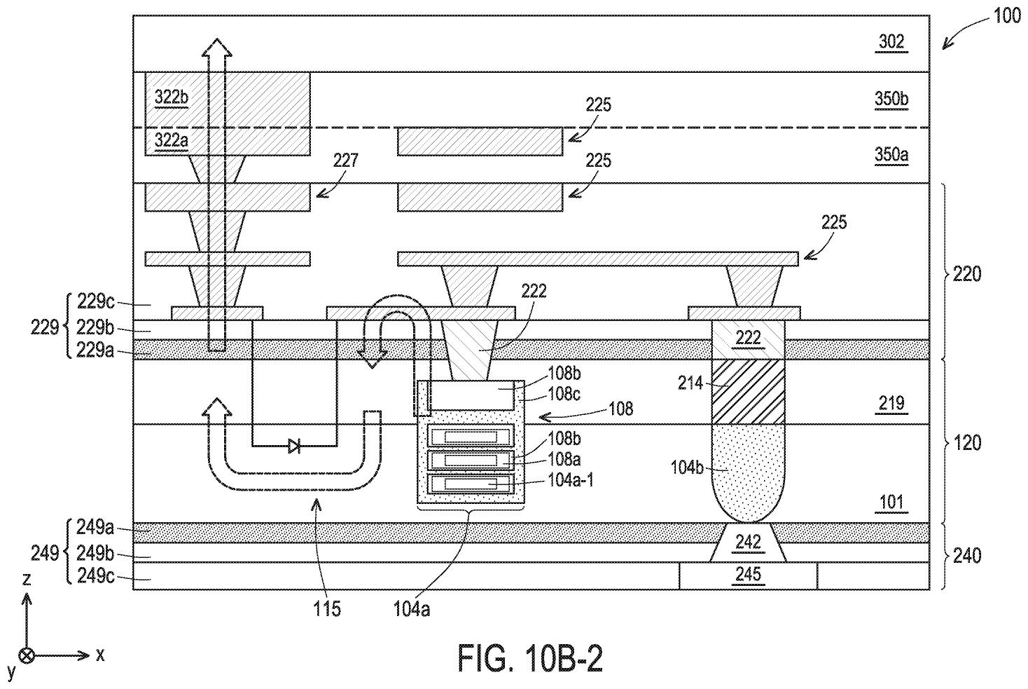

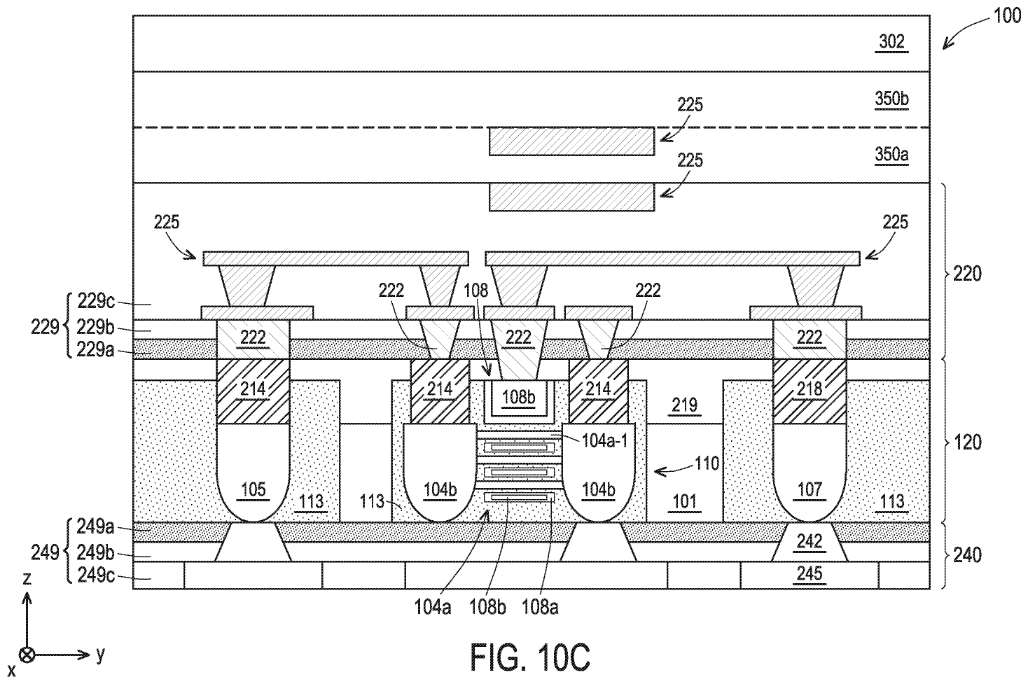

The gate stack 108 includes a gate electrode 108b over a gate dielectric 108a, and the gate dielectric 108a is disposed on the channel region 104a. In some embodiments, an interfacial layer (e.g., a silicon oxide layer) is disposed vertically between the channel region 104a and the gate dielectric 108a. The gate dielectric layer 108a includes a high-k dielectric material, such as materials having a dielectric constant greater than silicon oxide (k≈3.9). The gate dielectric layer 108b may include HfO, LaO, ZrO, AlO, TiO, or TaO. The gate electrode 108b includes a suitable conductive material, such as Al, W, Co, TiAl, TiN, or other metal gate materials. As shown in later figures (e.g., FIGS. 10B-1 and FIG. 10C), the gate dielectric layer 108a and the gate electrode 108b may each wrap around multiple transistor channels in a channel region 104a. Each channel regions 104a may further include spacer features (see e.g., spacer features 108c in FIG. 10B-1) such as gate spacers and inner spacers. The gate spacers may line sidewalls of the gate stack 108 above the topmost channels, and the inner spacers may be vertically disposed between transistor channels and laterally disposed between the gate stacks 108 and the S/D regions 104b. The gate spacers and the inner spacers may include silicon oxide, silicon nitride, silicon oxycarbide, silicon oxycarbonitride, silicon carbonitride, metal nitride, or a suitable dielectric material. In an embodiment, the spacer features are surrounded by oxide dielectric layers and thus the spacer features include silicon nitride for etchant selectivity.

Each of the S/D regions 104b may include epitaxial S/D features doped with n-type dopants and/or p-type dopants that sandwich transistor channels in the channel regions 104a. In some embodiments, for n-type transistors, the S/D regions 104b include epitaxial S/D features having silicon doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for p-type transistors, the S/D regions 104b include epitaxial S/D features having silicon germanium or germanium doped with boron, other p-type dopant, or combinations thereof (for example, forming Si:Ge:B epitaxial source/drain features). In some embodiments, portions of the epitaxial features closer to the transistor channels in the channel regions 104a have lower doping concentrations than portions of the epitaxial features laterally away from the transistor channels.

Still referring to FIG. 3, the method 1000 at operation 1004 forms PN junction structures 115 in the device layer 120. Each one of the PN junction structures 115 may be formed adjacent to one of the transistor devices 110. Although only one is shown, the present disclosure contemplates forming multiple pairs of PN junction structures 115 and transistor devices 110. The PN junction structure 115 is shown as a diode having two terminals, which corresponds to PN junction electrodes 217a and 217b. The two terminals are configured such that the PN junction structure 115 is reverse biased in operation. Each of the PN junction structures 115 includes a first doped region and a second doped region (not shown here but shown as 215a and 215b in FIG. 10B-1), and the first and the second doped regions are doped with opposite type dopants. The first doped region is electrically connected to the first terminal (i.e., PN junction electrode 217a), and the second doped region is electrically connected to the second terminal (i.e., PN junction electrode 217b). The first doped region and the PN junction electrode 217a may be electrically connected to a gate stack 108 in a later operation 1006, and the second doped region and the PN junction electrode 217b may be electrically connected to a carrier substrate 302 in a later operation 1012. Additional details of the PN junction structure 115 is described in later figures.

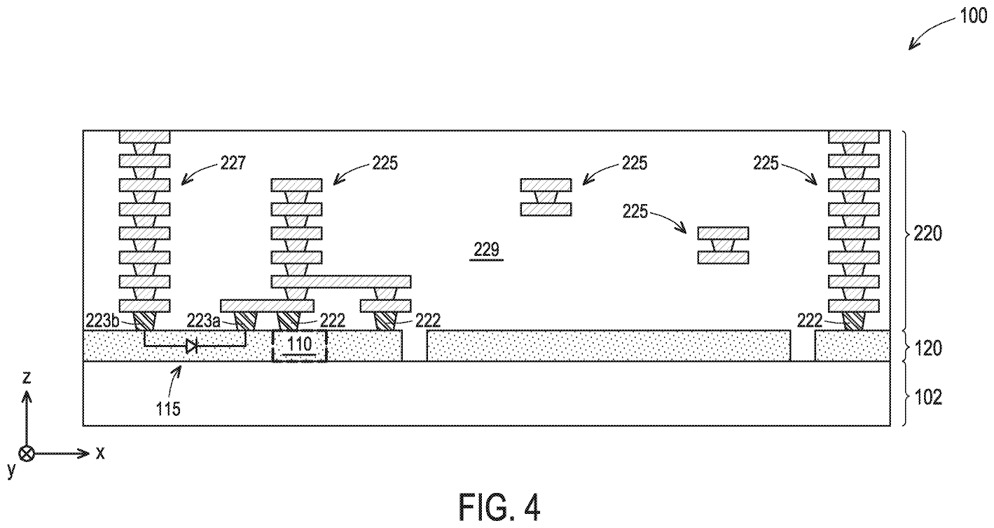

Referring now to FIG. 4, the method 1000 at operation 1006 forms a frontside interconnect structure 220 over the device layer 120. The frontside interconnect structure 220 includes frontside vias 222, 223a, and 223b and metal features 225 and 227 embedded in an intermetal dielectric (IMD) structure 229 as described above with respect to FIG. 1. These features may be formed by any suitable patterning and deposition processes. Some of the metal features 225 may be gate path metal lines 225 that electrically connect to one or more gate stacks 108 through one or more frontside vias 222 landing on the gate stacks 108. In an embodiment, a bottommost metal line of the gate path metal lines 225 lands on a frontside via 222 and a frontside via 223a, where the frontside via 222 lands on a gate stack 108, and the frontside via 223a lands on a first terminal (i.e., PN junction electrode 217a) of a PN junction structure 115. In an embodiment, metal features 227 (or thermal path metal lines 227) electrically connect to the second terminal of the PN junction structures 115 (i.e., PN junction electrode 217b) by landing on a frontside via 223b, where the frontside via 223b lands on the second terminal of the PN junction structures 115. As shown, the thermal path metal lines 227 are coupled to the gate path metal lines 225 by a PN junction structure 115 formed therebetween. Note that other metal features 225 are also shown and may couple to other components of other transistor devices 110.

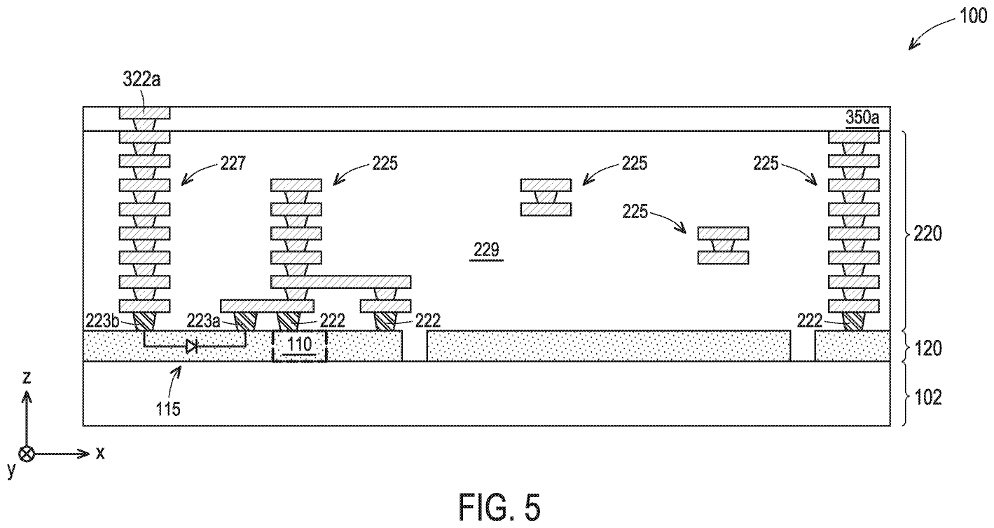

Referring now to FIG. 5, the method 1000 at operation 1008 deposits a first bonding oxide layer 350a over the frontside interconnect structure 220. The first bonding oxide layer 350a embeds first bonding metal contacts 322a landing on a top surface of the thermal path metal lines 227 (e.g., top metal line of the thermal path metal lines 227). In an embodiment, the first bonding oxide layer 350a includes silicon oxide. The first bonding oxide layer 350a may first be deposited over the interconnect structure 220 by any suitable deposition process, then the first bonding oxide layer 350a is patterned to form a trench, then the trench is filled with a metal material (e.g., copper) to form the bonding metal contact 322a. A planarization process may then be performed to planarize top surfaces of the bonding metal contact 322a and the bonding oxide layer 350a. The bonding metal contact 322a may include a wider metal contact portion over a narrower via portion and the different portions may be formed in a dual damascene process. In the present embodiment, the bonding metal contact 322a is made of copper.

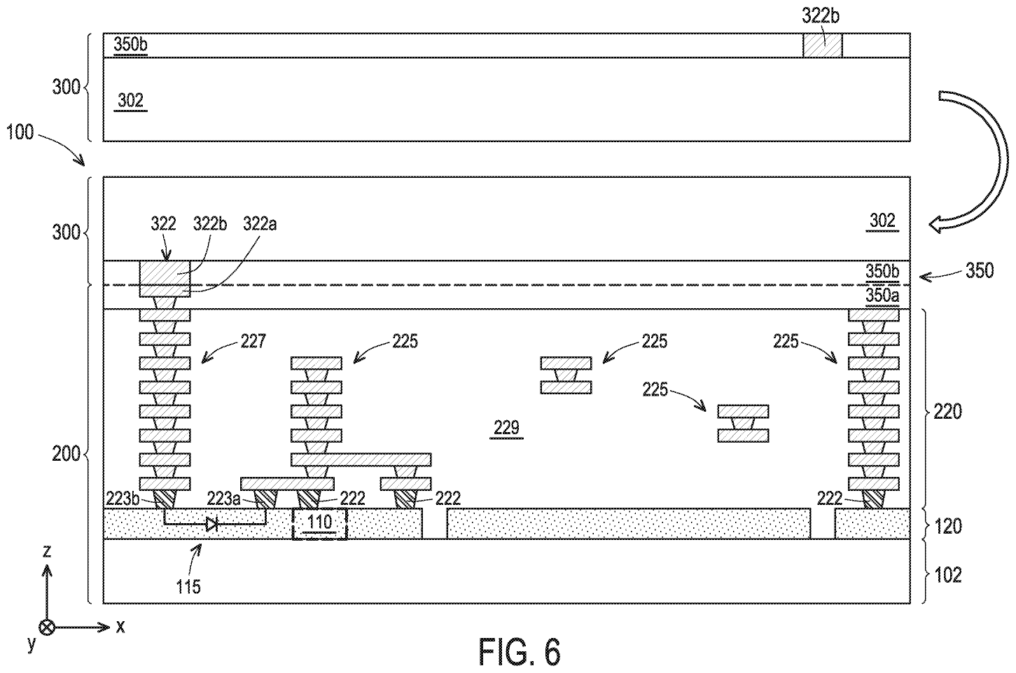

Referring now to FIG. 6, and particularly to the top figure, the method 1000 at operation 1010 forms a carrier wafer 300 having a second bonding oxide layer 350b over a carrier substrate 302. The second bonding oxide layer 350b embeds second bonding metal contacts 322b landing on the carrier substrate 302. These features have been described with respect to FIG. 1. The second bonding oxide layer 350b may first be deposited over a to surface of the carrier substrate 302 by any suitable deposition process, then the second bonding oxide layer 350b is patterned to form a trench, then the trench is filled with a metal material (e.g., copper) to form the bonding metal contact 322b. A planarization process may then be performed to planarize top surfaces of the bonding metal contact 322b and the bonding oxide layer 350b. In the present embodiment, the bonding metal contact 322b is made of copper.

Still referring to FIG. 6, and particularly to the bottom figure, the method 1000 at operation 1012 performs a bonding process to bond the first bonding oxide layer 350a to the second bonding oxide layer 350b such that the first bonding metal contacts 322a directly contact the second bonding metal contacts 322b. The bonding process may include flipping the carrier wafer 300 (or the device wafer 200) for front-side to front-side hybrid bonding at the dashed line interface. As shown, the device wafer 200 includes the substrate 102, the device layer 120, and the frontside interconnect structure 220. After the bonding process, a bonding oxide layer 350 is formed by the bonding oxide layers 350a and 350b, and bonding metal contacts 322 are formed by the bonding metal contacts 322a and 322b. The bonding metal contacts 322 penetrates through the bonding oxide layer 350 to create thermal paths from the carrier substrate 302 to the one or more transistor devices 110.

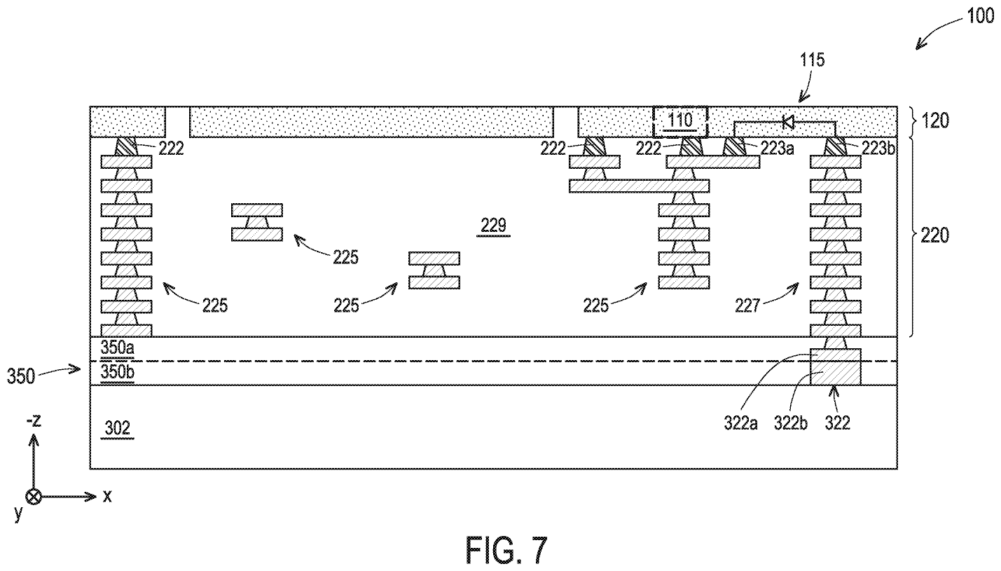

Referring now to FIG. 7, the method 1000 at operation 1014 thins down the substrate 102 from a backside to expose the transistor devices 110 in the device layer 120. Operation 1014 may be performed before or after the bonded semiconductor structure 100 is flipped for further backside processing. Due to the flip, the axis facing vertically up is now shown as the −Z direction. The operation 1014 thins down the exposed backside of the substrate 102 by a suitable process such as a mechanical grinding process and/or a chemical thinning process. In the embodiment shown, the thin down process fully removes the substrate 102 such that the device layer 120 is fully exposed on the backside. In other embodiments, the substrate 102 may be partially removed yet having portions of the device layer 120 exposed to expose components of the transistor devices 110 (e.g., gate stacks 108 and S/D regions 104b). In either case, due to the substrate 102 partially or fully removed, the substrate 102 is no longer able to or no longer efficient in absorbing heat caused by device self-heating. As such, the carrier substrate 302 supplements or replaces the heat absorbing function of the substrate 102 through the thermal path formed.

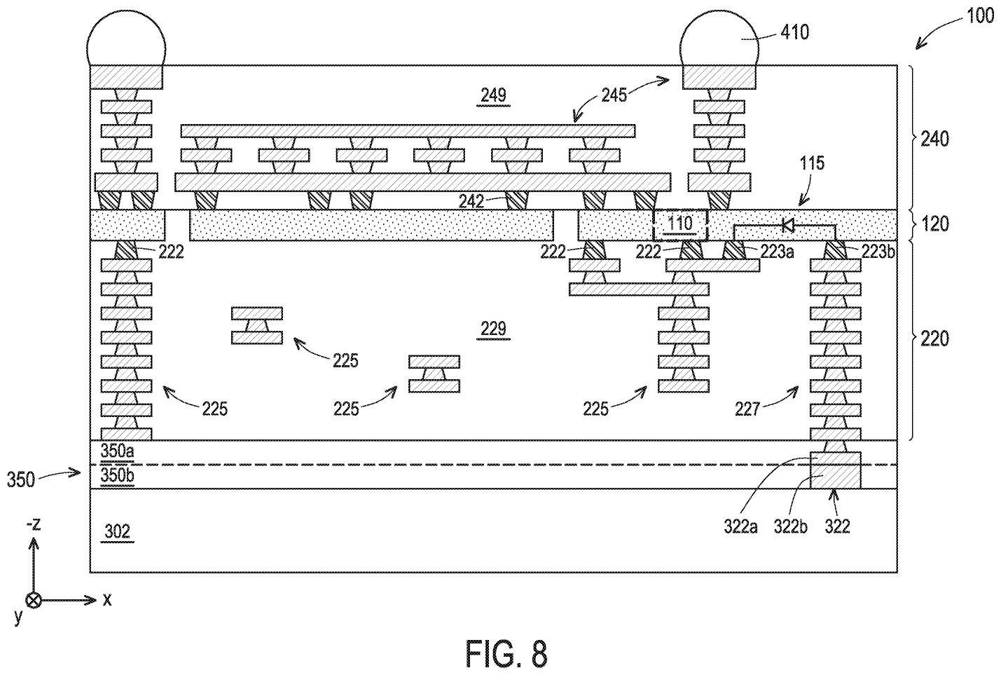

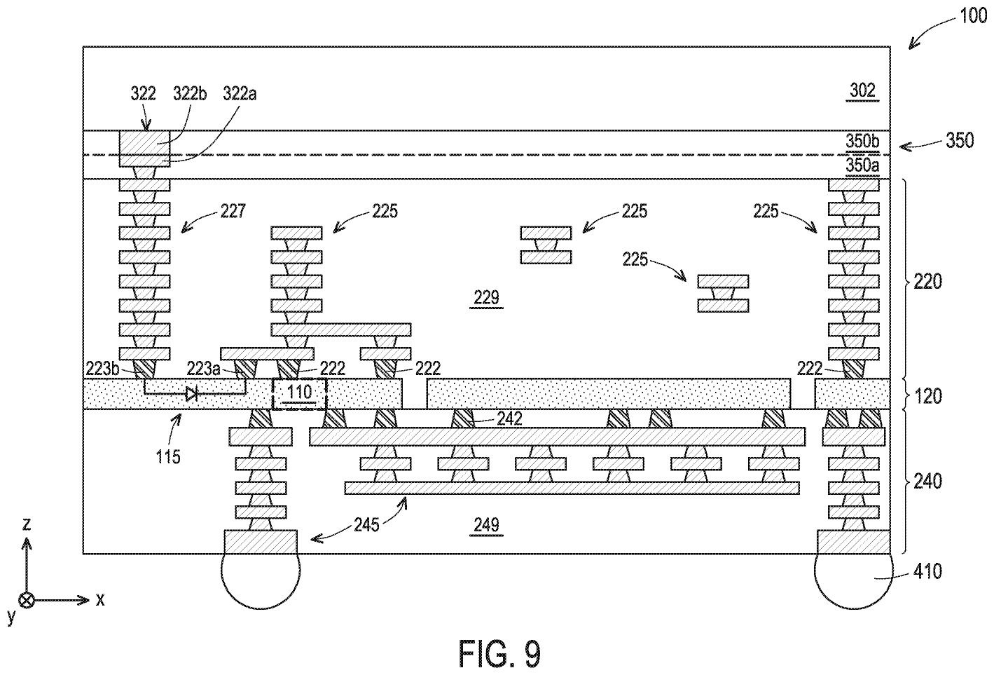

Referring now to FIG. 8, the method 1000 at operation 1016 forms a backside interconnect structure 240 on a backside of the device layer 120 and on the backside of the transistor devices 110. The backside interconnect structure 240 includes backside vias 242 and backside metal features 245 embedded in an intermetal dielectric (IMD) structure 249 as described above with respect to FIG. 1. These features may be formed by any suitable patterning and deposition processes. The backside metal features 245 may include metal lines and vias that electrically connect to one or more S/D regions 104b from a backside. In an embodiment, one or more metal lines of the backside metal features 245 may land on one or more backside vias 242, where the backside vias 242 land on the backside of one or more S/D regions 104b of the transistor devices 110. As part of operation 1016 or after operation 1016, the method 1000 may form bonding pads 410 that land on one or more of the backside metal features 245 as shown. The bonding pads 410 may be power and/or I/O bonding pads 410 that route to other circuit structures not shown. FIG. 9 illustrates FIG. 8 oriented in the positive z direction, which corresponds to FIG. 1 described above.

FIG. 10A illustrates a top view of a semiconductor structure 100 having multiple thermal conductive paths for multiple transistor devices 110. Note that FIG. 10A only shows certain features and omits other features for purpose of simplicity. In the embodiment shown, the semiconductor structure 100 includes active regions 104 formed as part of the transistor devices 110 previously described and active regions 104 formed as part of the PN junction structures 115 previously described. Each of the PN junction structures 115 includes an N-type doped region (e.g., first doped region 215a) and a P-type doped region (e.g., second doped region 215b) adjacent to each other. As shown, the semiconductor structure 100 may further include active regions 104 as part of other transistors and/or function as standalone epitaxial features. Gate stacks 108 extend lengthwise over channel regions 104a of the various active regions 104. The semiconductor structure 100 further includes thermal path metal lines 227 that routes to a common carrier substrate 302 (not shown here). The various features described in FIG. 10A may be isolated from each other by an isolation structure 101. The isolation structure 101 may include silicon oxide, silicon oxynitride, fluorine-doped silicate glass (FSG), a low-k dielectric, combinations thereof, and/or other suitable materials.

Still referring to FIG. 10A, the gate stacks 108 are electrically connected to first terminals of the PN junction structures 115. The first terminals electrically connects to first doped regions 215a such as n-type doped regions of the PN junction structures 115. The thermal path metal lines 227 are electrically connected to second terminals of the PN junction structures 115. The second terminals electrically connects to second doped regions 215b such as P-type doped regions of the PN junction structures 115. In other embodiments, the N-type doped regions and the P-type doped regions are switched. For example, if the transistor devices 110 are n-type transistors having n-type source/drain features, the first doped regions 215a are n-type doped and the second doped regions 215b are p-type doped. And if the transistor devices 110 are p-type transistors having p-type source/drain features, the first doped regions 215a are p-type doped and the second doped regions 215b are n-type doped. These orientations are to facilitate reverse bias conditions during circuit operation.

FIG. 10B-1 illustrates a cross-sectional view of a semiconductor structure 100 cut along the lines B-B′ in FIG. 10A, according to an embodiment of the present disclosure. Note that FIG. 10B-1 resembles a zoomed-in portion of FIG. 1 (or FIG. 9) with features previously described similarly labeled. The similar features will not be described again for the sake of brevity. However, FIG. 10B-1 shows more detailed features regarding the device layer 120, which includes details of the PN junction structure 115, the gate stack 108, and other device layer components in the device layer 120. FIG. 10B-1 further shows more detailed features regarding example dielectric layers within the frontside interconnect structure 220 and the backside interconnect structure 240.

Referring to FIG. 10B-1, the gate stack 108 may be a part of a gate structure having the gate stack 108 (which includes the gate dielectric 108a and the gate electrode 108b) and spacer features 108c. The gate structure is disposed over a channel region 104a, which may include a stack of transistor channels 104a-1. The gate dielectric 108a may wrap around the transistor channels 104a-1, and bottom portions of the gate electrode 108b may wrap around the gate dielectric 108a. A top portion of the gate electrode 108b is disposed over the stack of transistor channels 104a-1.

Still referring to FIG. 10B-1, the PN junction structure 115 is a semiconductor active region configured differently from the active regions 104 of the transistor devices 110. The PN junction structure 115 includes a semiconductor portion 208 where a first doped region 215a and a second doped region 215b is formed therein. For example, the far ends of the semiconductor portion 208 may be recessed to form trenches, and the first doped region 215a and the second doped region 215b are formed by growing respective doped epitaxial features within the trenches. The first doped region 215a is doped with an opposite-type dopant as the second doped region 215b. In the present embodiment, the first doped region 215a is doped with an n-type dopant and the second doped region 215b is doped with a p-type dopant. In this case, the gate stack 108 coupled to the first doped region 215a is a gate stack 108 of an n-type transistor device 110 where S/D regions of the transistor device 110 are n-type doped. In an embodiment, the first doped region 215a doped with an n-type dopant includes epitaxial features doped with carbon, phosphorous, arsenic, other n-type dopant, or combinations thereof (for example, forming Si:C epitaxial features, Si:P epitaxial features, or Si:C:P epitaxial features). In an embodiment, the second doped region 215b doped with a p-type dopant includes epitaxial features doped with boron, other p-type dopant, or combinations thereof (for example, forming Si:Ge:B epitaxial features). Note that in alternative embodiments, the first doped region 215a is doped with a p-type dopant and the second doped region 215b is doped with an n-type dopant. In this case, the gate stack 108 coupled to the first doped region 215a is a gate stack 108 of a p-type transistor device 110 where S/D regions of the transistor device 110 are p-type doped. In an embodiment, the first doped region 215a doped with a p-type dopant includes epitaxial features doped with boron, other p-type dopant, or combinations thereof (for example, forming Si:Ge:B epitaxial features). In an embodiment, the second doped region 215b doped with an n-type dopant includes epitaxial features doped with carbon, phosphorous, arsenic, other n-type dopant, or combinations thereof (for example, forming Si:C epitaxial features, Si:P epitaxial features, or Si:C:P epitaxial features).

In the present embodiment, the semiconductor portion 208 includes a stack of interleaving silicon channels 204 and silicon germanium channels 206, which may be formed as part of forming GAA devices in other portions of the semiconductor structure 100. However, the present disclosure is not limited thereto, and the semiconductor portion 208 may be formed of a single semiconductor layer (e.g., silicon).

In the present embodiment, the first and second doped regions 215a and 215b are separated by a channel portion of the semiconductor portion 208, which acts as a channel therebetween. In the present embodiment, this channel portion may include a stack of interleaving silicon channels 204 and silicon germanium channels 206. The channel portion may be doped with a p-type dopant or an n-type dopant. In some cases, the channel portion is more lightly doped than the first and second doped regions 215a and 215b. If the channel portion is doped with a p-type dopant, an interface between the channel portion and an n-type doped first doped region 215a may define the PN junction. If the channel portion is doped with an n-type dopant, an interface between the channel portion and a p-type doped second doped region 215a may define the PN junction. However, in some embodiments, the first and second doped regions 215a and 215b may directly abut each other to share a common interface. In this case, there is no channel portion between the first and second doped regions 215a and 215b, and the common interface between the first and second doped regions 215a and 215b defines the PN junction. In any case, the PN junction of the PN junction structure 115 will be reverse biased during operation as indicated by the diode.

The PN junction structure 115 further includes PN junction electrodes 217a and 217b that function as first and second terminals of the reverse diode. The PN junction electrode 217a lands on a top surface of the first doped region 215a, and the PN junction electrode 217b lands on a top surface of the second doped region 215a. The PN junction electrodes 217a and 217b may include suitable metal materials such as Al, W, Co, TiAl, TiN, or other metal materials.

Still referring to FIG. 10B-1, assuming that the gate stack 108 is a gate stack 108 of a first transistor device 110, the device layer 120 may include an S/D region 104b of a second transistor device 110. And the S/D region 104b of the second transistor device is laterally adjacent to the gate stack 108 of the first transistor device 110, where the gate stack 108 of the first transistor device 110 is laterally adjacent to the PN junction structure 115. An S/D contact 214 is disposed over and landing on the S/D region 104b. The S/D contact 214 may include similar materials as the PN junction electrodes 217a and 217b. As shown, the device layer 120 includes an isolation structure 101 that embeds and surrounds the PN junction structure 115, the gate stack 108, and the S/D region 104b. The isolation structure 101 may have a top surface substantially coplanar with top surfaces of the PN junction structure 115 and the S/D region 104b. And a top surface of the gate stack 108 may be above top surfaces of the PN junction structure 115, the isolation structure 101, and the S/D region 104b. The device layer 120 further includes an interlayer dielectric (ILD) layer 219 disposed over the isolation structure 101. The ILD layer 219 embeds and surrounds the PN junction electrodes 217a and 217b, the gate stack 108, and the S/D contact 214. The ILD layer 219 may have a top surface substantially coplanar with top surfaces of the PN junction electrodes 217a and 217b and the S/D contact 214. And a top surface of the ILD layer 219 may be above the top surface of the gate stack 108. The ILD layer 219 may include an oxide formed with tetraethylorthosilicate, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. In an embodiment, the isolation structure 101 and the ILD layer 219 are formed of different dielectric materials for etchant selectivity (e.g., the isolation structure 101 is formed of silicon oxide, and the ILD layer 219 is formed of a low-k dielectric).

As described previously, a frontside interconnect structure 220 is disposed over the device layer 120. The frontside interconnect structure 220 includes an IMD structure 229 that embeds and surrounds various metal features previously described. In an embodiment, the IMD structure 229 may have a first layer 229a, a second layer 229b over the first layer 229a, and a third layer 229c over the second layer 229b. The first layer 229a may include silicon nitride, the second layer 229b may include silicon oxide, and the third layer 229c may include silicon oxide, silicon oxynitride, fluorine-doped silicate glass (FSG), a low-k dielectric, combinations thereof, and/or other dielectric suitable materials. The first and second layers 229a and 229b may embed and surround the frontside vias 222, 223a, and 223b landing on the device layer 120, and the third layer 229c may embed and surround the metal features 225 and 227. The first layer 229a, the second layer 229b, and the third layer 229c may be configured to have different materials for etchant selectivity when forming the various embedded metal features.

As described previously, a backside interconnect structure 240 is disposed on a backside of the device layer 120. The backside interconnect structure 240 includes an IMD structure 249 that embeds and surrounds various metal features previously described. In an embodiment, the IMD structure 249 may have a first layer 229a, a second layer 229b over the first layer 229a, and a third layer 229c over the second layer 229b. The first layer 249a may include silicon nitride, the second layer 249b may include silicon oxide, and the third layer 249c may include silicon oxide, silicon oxynitride, fluorine-doped silicate glass (FSG), a low-k dielectric, combinations thereof, and/or other suitable dielectric materials. The first and second layers 249a and 249b may embed and surround the backside vias 242 landing on S/D regions 104b, and the third layer 249c may embed and surround the metal features 245. The first layer 249a, the second layer 249b, and the third layer 249c may be configured to have different materials for etchant selectivity when forming the various embedded metal features.

As described previously and shown in FIG. 10B-1, thermal path metal features 227 routes to the carrier substrate 302 via the bonding metal contacts 322a and 322b, which are embedded in the bonding oxide layer 350a and 350b. Note that in some embodiments, there may be other metal contacts or metal features 225 embedded in the bonding oxide layer 350a for further device signal routing. However, these metal features 225 do not electrically connect to the carrier substrate 302. As shown, the bonding oxide layer 350 insulates these metal features 225 from being in metal contact with the carrier substrate 302. Since the metal features 225 are not electrically isolated by any PN junction structures 115, the bonding oxide layer 350 prevents any unwanted shorting effect.

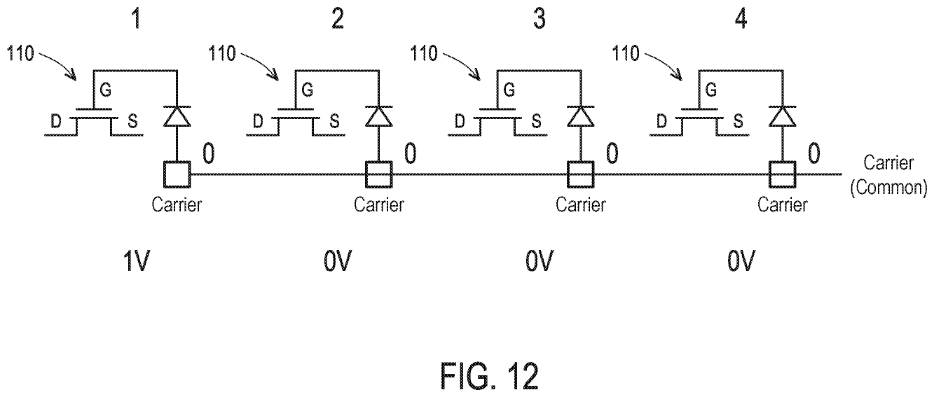

FIG. 10B-2 illustrates the mechanism of releasing heat from a transistor device 110 according to the semiconductor structure 100 of FIG. 10B-1. Although heat may be generated in other parts of the transistor device 110 (e.g., S/D regions 104b), thermal energy is mainly generated in the channels of the channel region 104a. Since the gate stack 108 has greater coupling surface with the channels than the S/D regions 104b, it is more effective to route a thermal path to the gate stack 108 than to the S/D regions. As shown by the dashed arrows, a thermal path from the gate stack 108 to the carrier substrate 302 allows thermal energy generated by the transistor device 110 to be absorbed by the carrier substrate 302. Without the thermal path to the carrier substrate 302, thermal energy is trapped and is poorly absorbed by the various dielectric layers, such as the bonding oxide layers 350a and 350b. With the thermal path to the carrier substrate 302, thermal absorption is significantly improved. For example, studies have shown that silicon may have 120 times better thermal conductance than dielectric oxides. With a carrier substrate 302 having silicon, thermal energy may be relaxed by 120 times. As will be described further with respect to FIG. 12, although a thermal path is created, the PN junction structure 115 prevents a signal path to the carrier substrate 302. That is, the PN junction structure 115 prevents electrical coupling between the gate stack 108 and the carrier substrate 302 while allowing thermal coupling between the gate stack 108 and the carrier substrate 302.

FIG. 10C illustrates a cross-sectional view of a semiconductor structure 100 cut along the lines C-C′ in FIG. 10A, according to an embodiment of the present disclosure. FIG. 10C illustrates similarly labeled features as in FIG. 10B-1 and these features will not be described again for the sake of brevity. As shown, a transistor device 110 includes a channel region 104a having multiple transistor channels 104a-1 connecting between S/D regions 104b. The transistor channels 104a-1 are wrapped around by a gate stack 108 having a gate dielectric 108a and a gate electrode 108b over the gate dielectric 108a. The gate stack 108 may be thermally routed to the carrier substrate 302 as described above. A dielectric structure 113 surrounds and embeds the gate stack 108, the S/D regions 104b, and a portion of the S/D contacts 214 over the S/D regions 104b. This dielectric structure 113 may include spacer features 108c previously described as well as other dielectric layers. In an embodiment, the dielectric structure 113 includes silicon nitride. Note that one of the S/D regions 104b may route to an adjacent active region having epitaxial features 105, and to backside metal features 245 that correspond to the drain node of the transistor device 110. Note that another one of the S/D regions 104b may directly route to backside metal features 245 that correspond to the source node of the transistor device 110 (e.g., directly through a backside via 242 between the S/D region 104b and the backside metal features 245). Note that the gate electrode 108b of the gate stack 108 may route to an adjacent active region having epitaxial features 107, and to backside metal features 245 that corresponds to the gate node of the transistor device 110. The epitaxial features 105 and 107 are extension epitaxial features that provide spacing margins for routing the drain, source, and gate terminals of the transistor device 110. An S/D contact 214 is disposed above and landing on the epitaxial feature 105, and a gate contact 218 is disposed above and landing on the epitaxial feature 105. The S/D regions 104b, the epitaxial features 105 and 107, the S/D contacts 214, and the gate contact 218 are surrounded and embedded in dielectric structures 113 previously described.

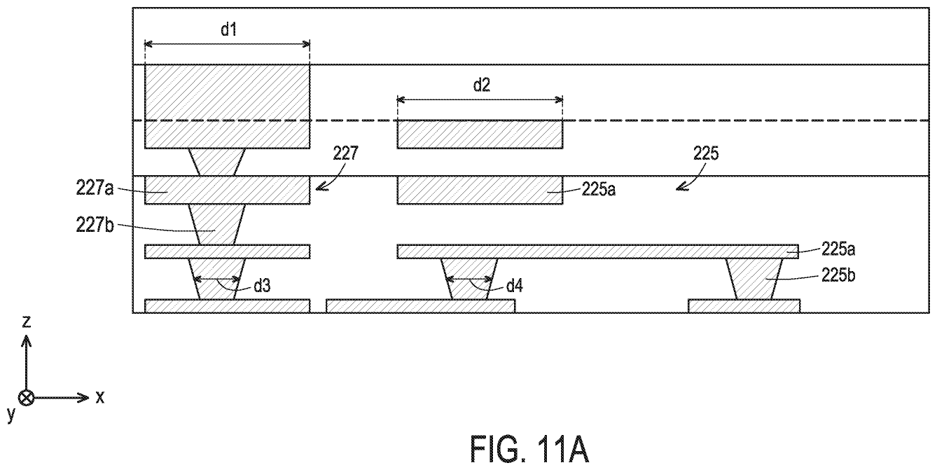

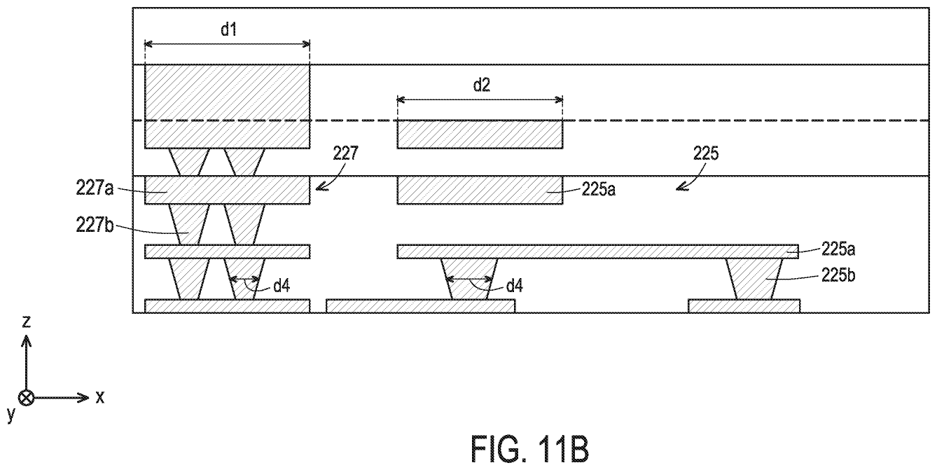

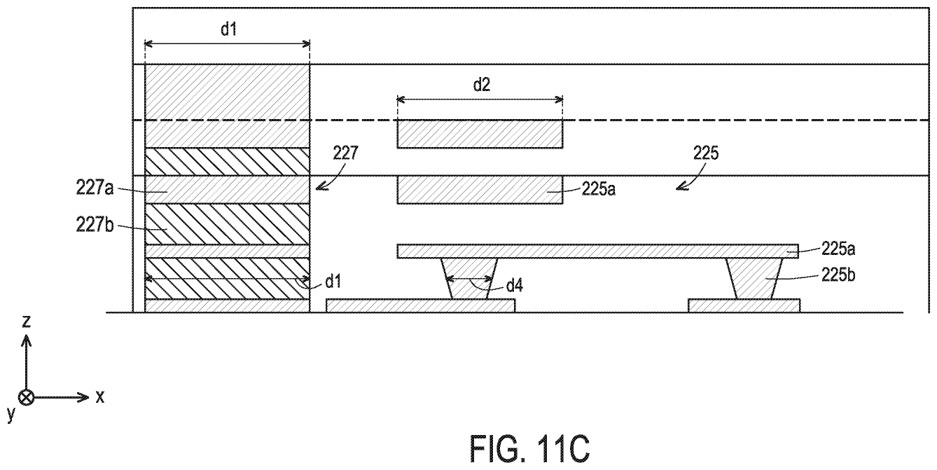

FIGS. 11A-11C illustrates metal line and metal via dimensions for thermal conductive paths and for functional circuit paths, according to various embodiments of the present disclosure. The metal line and metal vias as part of the thermal path metal lines 227 are labeled as metal lines 227a and metal vias 227b. And the metal line and metal vias as part of the functional circuit paths such as gate path metal lines 225 are labeled as metal lines 225a and metal vias 225b. In the embodiments shown in FIGS. 11A-11C, the metal lines 227a may generally be shorter than the metal lines 225a. This is because the metal lines 227a need not route to other vias that connect to signal or power line connections. Instead, the metal lines 227a need only provide a vertical path to the carrier substrate 302. In an embodiment, the metal lines 227a have a width d1, the shortest metal lines 225a have a width d2, and the metal lines 227a are shorter than the shortest metal lines 225a.

As shown in FIG. 11A, the metal vias 227b may have a greater size (e.g., wider in the x direction) than the metal vias 225b. For example, the metal vias 227b have a width d3, the metal vias 225b have a width d4, and the width d3 is greater than the width d4. The wider size increases surface contact to the metal lines 227a. As shown in FIG. 11B, the metal vias 227b may have a similar size as the metal vias 225b. For example, both the metal vias 227b and 225b have a width d4. However, there may be multiple metal vias 227b that connect between the metal lines 227a for increased surface contact. As shown in FIG. 11C, the metal vias 227b may have a similar size as the metal lines 227a to maximize surface contact. For example, both the metal vias 227b and 225b have a width d1. In any case, short metal lines 227a but dense group of metal vias 227b or even large metal vias 227b (such as slot vias) may be used for efficient thermal connection.

FIG. 12 illustrates a circuit diagram of multiple transistor devices 110 with their gates coupled to a carrier, such as the carrier substrate 302 described above. As shown, there are multiple thermal paths that couple between the respective gates and a common carrier. Each of the thermal paths includes a reverse-biased diode therebetween, which may be implemented by a PN junction structure 115 described herein. The reverse diodes prevents the gates of the multiple transistor devices 110 from shorting together by the common carrier. For example, when a voltage of 1V is applied to a first transistor device 110, the gates of a second, third, and fourth transistor device 110 remain at 0V. This is because the reverse-biased diode coupled to the first transistor device 110 blocks electrical signals from reaching the common carrier. Nevertheless, thermal energy is still transferred to the common carrier via the thermal path. In similar fashion, if a voltage is applied to the second, third, or fourth transistor devices 110, the gates of the other transistor devices 110 will remain at 0V due to the respective revers-biased diodes.

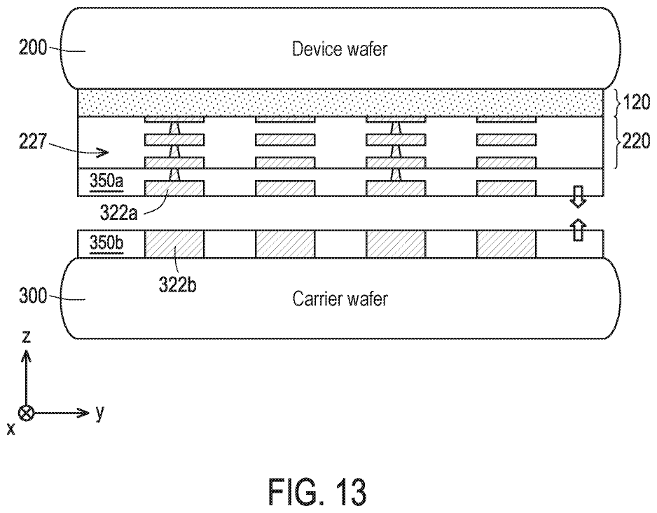

FIG. 13 illustrates the bonding between a device wafer 200 to a carrier wafer 300, according to an embodiment of the present disclosure. As shown, the bonding may bond multiple bonding metal contacts 322a to multiple bonding metal contacts 322b. Each bond between a metal contact 322a and a metal contact 322b completes a thermal path for a transistor device 110. The multiple thermal paths are electrically isolated from each other by the reverse-biased diodes as configured and described with respect to FIG. 12.

Although not limiting, the present disclosure offers advantages for semiconductor structures having backside features by incorporating a thermal path between transistor devices and a carrier substrate. One example advantage is having the carrier substrate absorb heat generated by the transistor devices. Another example advantage is targeting connection to the gate of the transistor devices to maximize thermal relaxation. Another example advantage is to have multiple transistor devices thermally coupled to a common carrier substrate. Another example advantage is incorporating PN junction structures that electrically isolate between different thermal paths to prevent shorting issues.

One aspect of the present disclosure pertains to a semiconductor structure. The semiconductor structure includes a device layer having a transistor device and a PN junction structure coupled to the transistor device, the transistor device includes a channel region between source/drain (S/D) regions and a gate stack over the channel region, the PN junction structure includes a first doped region and a second doped region, and the first doped region is electrically connected to the gate stack. The semiconductor structure includes a frontside interconnect structure over a frontside of the device layer, the frontside interconnect structure includes thermal path metal features electrically connected to the second doped region of the PN junction structure. The semiconductor structure includes a bonding oxide layer over the frontside interconnect structure, the bonding oxide layer embeds a thermal path metal contact electrically connected to the thermal path metal features. The semiconductor structure includes a carrier substrate over the bonding oxide layer, the carrier substrate landing on a top surface of the thermal path metal contact.

In an embodiment, the carrier substrate is of a semiconductor material.

In an embodiment, the thermal path metal features include metal lines vertically disposed between metal vias, and the frontside interconnect structure further includes an intermetal dielectric (IMD) layer embedding the metal lines and metal vias.

In an embodiment, the frontside interconnect structure further includes frontside gate metal features electrically connected to the gate stack.

In an embodiment, the device layer further includes another transistor device, further comprising: a backside interconnect structure over a backside of the device layer, where the backside interconnect structure includes backside metal features electrically connected to an S/D region of the another transistor device, and the S/D region of the another transistor device is electrically connected to the gate stack through frontside gate metal features in the frontside interconnect structure.

In a further embodiment, the device layer further includes an isolation layer embedding the transistor device, the another transistor device, and the PN junction structure, where the backside metal features include a backside via having a top surface substantially coplanar with a bottom surface of the isolation layer.

In an embodiment, the first doped region is adjacent the second doped region, the first doped region is doped with a first type dopant, the second doped region is doped with a second type dopant opposite the first type dopant.

In a further embodiment, the S/D regions of the transistor device are doped with an n-type dopant, the first doped region is doped with an n-type dopant, and the second doped region is doped with a p-type dopant.

In a further embodiment, the S/D regions of the transistor device are doped with a p-type dopant, the first doped region is doped with a p-type dopant, and the second doped region is doped with an n-type dopant.

In an embodiment, the device layer further includes a second transistor device and a second PN junction structure coupled to the second transistor device, the second transistor device includes a second channel region between second S/D regions and a second gate stack over the second channel region, the second PN junction structure includes a third doped region and a fourth doped region, and the third doped region is electrically connected to a gate electrode of the second gate stack. The frontside interconnect structure further includes second thermal path metal features electrically connected to the fourth doped region of the second PN junction structure. The bonding oxide layer embeds a second thermal path metal contact electrically connected to the second thermal path metal features. The carrier substrate lands on a top surface of the second thermal path metal contact.

Another aspect of the present disclosure pertains to a semiconductor structure. The semiconductor structure includes transistor devices having channel regions between source/drain (S/D) regions and gate stacks over the channel regions. The semiconductor structure includes PN junction structures having first doped regions and second doped regions oppositely doped from the first doped regions, and the first doped regions are electrically connected to the gate stacks. The semiconductor structure includes thermal path metal features over the PN junction structures and electrically connected to the second doped regions of the PN junction structure. The semiconductor structure includes a carrier substrate over the thermal path metal features and in metal contact with the thermal path metal features.

In an embodiment, the semiconductor structure further includes a bonding oxide layer between the thermal path metal features and the carrier substrate; and thermal path metal contacts in direct contact with the carrier substrate and penetrating through the bonding oxide layer to land on top metal features of the thermal path metal features.

In an embodiment, the semiconductor structure further includes an isolation structure embedding the transistor devices and the PN junction structures; an interlayer dielectric (ILD) structure over the isolation structure and embedding gate vias landing on the gate stacks, first metal electrodes landing on the first doped regions, second metal electrodes landing on the second doped regions, first PN junction vias landing on the first metal electrodes, and second PN junction vias landing on the second metal electrodes; and a frontside interconnect structure over the ILD structure, the frontside interconnect structure having an intermetal dielectric (IMD) structure embedding first metal lines landing on the gate vias and the first PN junction vias and second metal lines landing on the second PN junction vias. Top surfaces of the first and the second metal lines are substantially coplanar.

In a further embodiment, the thermal path metal features include thermal path metal lines vertically disposed between thermal path metal vias, and the first metal lines are bottommost metal lines of the thermal path metal lines.

In a further embodiment, the semiconductor structure further includes second transistor devices having second channel regions between second S/D regions and second gate stacks over the second channel regions, and one of the second S/D regions is electrically connected to one of the gate stacks by a conductive path having a via landing on the second metal lines.

In an embodiment, the first doped regions are laterally adjacent to the second doped regions, and the first doped regions are separated from the second doped regions by doped channels.

Another aspect of the present disclosure pertains to a method of forming a semiconductor structure. The method includes forming transistor devices in a device layer over a substrate, each transistor device having a channel region between source/drain (S/D) regions and a gate stack over the channel region; forming PN junction structures in the device layer, each PN junction structure having a first doped region and a second doped region oppositely doped from the first doped region, the first doped region is electrically connected to one of the gate stacks; forming a frontside interconnect structure over the device layer, the frontside interconnect structure includes gate path metal lines electrically connected to the gate stacks and thermal path metal lines electrically connected to the second doped regions of the PN junction structures; depositing a first bonding oxide over the frontside interconnect structure, the first bonding oxide embeds first bonding metal contacts landing on a top surface of the thermal path metal lines; forming a carrier wafer structure having a second bonding oxide over a carrier substrate, the second bonding oxide embeds second bonding metal contacts landing on the carrier substrate; performing a bonding process to bond the first bonding oxide to the second bonding oxide such that the first bonding metal contacts directly contact the second bonding metal contacts; thinning down the substrate from a backside to expose the transistor devices in the device layer; and forming a backside interconnect structure on a backside of the transistor devices.

In an embodiment, the method further includes forming second transistor devices in the device layer, each of the second transistor devices having a second channel region between second source/drain (S/D) regions and a second gate stack over the second channel region. The forming of the backside interconnect structure includes forming backside metal features electrically connected to the second source/drain (S/D) regions. The second S/D region is electrically connected to the one of the gate stacks.

In an embodiment, the forming of the carrier wafer structure includes forming the second bonding oxide over the carrier substrate; patterning the second bonding oxide to form trenches exposing the carrier substrate; and forming the second bonding metal contacts in the trenches.

In an embodiment the method further includes forming gate vias over the gate stacks of the transistor devices; forming first metal electrodes landing on the first doped regions; forming second metal electrodes landing on the second doped regions; forming first PN junction vias landing on the first metal electrodes; and forming second PN junction vias landing on the second metal electrodes. Forming the frontside interconnect structure includes forming a bottom metal line of the gate path metal lines landing on the gate vias and the first PN junction vias and a bottom metal line of the thermal path metal lines landing on the second PN junction vias. Top surfaces of the bottom metal lines of the gate path metal lines and the thermal path metal lines are substantially coplanar.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a device layer having a transistor device and a PN junction structure coupled to the transistor device, the transistor device includes a channel region between source/drain (S/D) regions and a gate stack over the channel region, the PN junction structure includes a first doped region and a second doped region, and the first doped region is electrically connected to the gate stack;
a frontside interconnect structure over a frontside of the device layer, the frontside interconnect structure includes thermal path metal features electrically connected to the second doped region of the PN junction structure;
a bonding oxide layer over the frontside interconnect structure, the bonding oxide layer embeds a thermal path metal contact electrically connected to the thermal path metal features; and
a carrier substrate over the bonding oxide layer, the carrier substrate landing on a top surface of the thermal path metal contact.

2. The semiconductor structure of claim 1, wherein the carrier substrate is of a semiconductor material.

3. The semiconductor structure of claim 1, wherein the thermal path metal features include metal lines vertically disposed between metal vias, and the frontside interconnect structure further includes an intermetal dielectric (IMD) layer embedding the metal lines and metal vias.

4. The semiconductor structure of claim 1, wherein the frontside interconnect structure further includes frontside gate metal features electrically connected to the gate stack.

5. The semiconductor structure of claim 1, wherein the device layer further includes another transistor device, further comprising:
a backside interconnect structure over a backside of the device layer,
wherein the backside interconnect structure includes backside metal features electrically connected to an S/D region of the another transistor device,
wherein the S/D region of the another transistor device is electrically connected to the gate stack through frontside gate metal features in the frontside interconnect structure.

6. The semiconductor structure of claim 5, wherein the device layer further includes an isolation layer embedding the transistor device, the another transistor device, and the PN junction structure, wherein the backside metal features include a backside via having a top surface substantially coplanar with a bottom surface of the isolation layer.

7. The semiconductor structure of claim 1,
wherein the first doped region is adjacent the second doped region, the first doped region is doped with a first type dopant, the second doped region is doped with a second type dopant opposite the first type dopant.

8. The semiconductor structure of claim 7,
wherein the S/D regions of the transistor device are doped with an n-type dopant,
wherein the first doped region is doped with an n-type dopant, and the second doped region is doped with a p-type dopant.

9. The semiconductor structure of claim 7,
wherein the S/D regions of the transistor device are doped with a p-type dopant,
wherein the first doped region is doped with a p-type dopant, and the second doped region is doped with an n-type dopant.

10. The semiconductor structure of claim 1,
wherein the device layer further includes a second transistor device and a second PN junction structure coupled to the second transistor device, the second transistor device includes a second channel region between second S/D regions and a second gate stack over the second channel region, the second PN junction structure includes a third doped region and a fourth doped region, and the third doped region is electrically connected to a gate electrode of the second gate stack,
wherein the frontside interconnect structure further includes second thermal path metal features electrically connected to the fourth doped region of the second PN junction structure,
wherein the bonding oxide layer embeds a second thermal path metal contact electrically connected to the second thermal path metal features,
wherein the carrier substrate lands on a top surface of the second thermal path metal contact.

11. A semiconductor structure, comprising:
transistor devices having channel regions between source/drain (S/D) regions and gate stacks over the channel regions;
PN junction structures having first doped regions and second doped regions oppositely doped from the first doped regions, and the first doped regions are electrically connected to the gate stacks;
thermal path metal features over the PN junction structures and electrically connected to the second doped regions of the PN junction structure; and
a carrier substrate over the thermal path metal features and in metal contact with the thermal path metal features.

12. The semiconductor structure of claim 11, further comprising:
a bonding oxide layer between the thermal path metal features and the carrier substrate; and
thermal path metal contacts in direct contact with the carrier substrate and penetrating through the bonding oxide layer to land on top metal features of the thermal path metal features.

13. The semiconductor structure of claim 11, further comprising:
an isolation structure embedding the transistor devices and the PN junction structures;
an interlayer dielectric (ILD) structure over the isolation structure and embedding gate vias landing on the gate stacks, first metal electrodes landing on the first doped regions, second metal electrodes landing on the second doped regions, first PN junction vias landing on the first metal electrodes, and second PN junction vias landing on the second metal electrodes; and
a frontside interconnect structure over the ILD structure, the frontside interconnect structure having an intermetal dielectric (IMD) structure embedding first metal lines landing on the gate vias and the first PN junction vias and second metal lines landing on the second PN junction vias, wherein top surfaces of the first and the second metal lines are substantially coplanar.

14. The semiconductor structure of claim 13, wherein the thermal path metal features include thermal path metal lines vertically disposed between thermal path metal vias, and the first metal lines are bottommost metal lines of the thermal path metal lines.

15. The semiconductor structure of claim 13, further comprising:
second transistor devices having second channel regions between second S/D regions and second gate stacks over the second channel regions, and one of the second S/D regions is electrically connected to one of the gate stacks by a conductive path having a via landing on the second metal lines.

16. The semiconductor structure of claim 11, wherein the first doped regions are laterally adjacent to the second doped regions, and the first doped regions are separated from the second doped regions by doped channels.

17. A method of forming a semiconductor structure, comprising:
forming transistor devices in a device layer over a substrate, each transistor device having a channel region between source/drain (S/D) regions and a gate stack over the channel region;
forming PN junction structures in the device layer, each PN junction structure having a first doped region and a second doped region oppositely doped from the first doped region, the first doped region is electrically connected to one of the gate stacks;
forming a frontside interconnect structure over the device layer, the frontside interconnect structure includes gate path metal lines electrically connected to the gate stacks and thermal path metal lines electrically connected to the second doped regions of the PN junction structures;
depositing a first bonding oxide over the frontside interconnect structure, the first bonding oxide embeds first bonding metal contacts landing on a top surface of the thermal path metal lines;
forming a carrier wafer structure having a second bonding oxide over a carrier substrate, the second bonding oxide embeds second bonding metal contacts landing on the carrier substrate;
performing a bonding process to bond the first bonding oxide to the second bonding oxide such that the first bonding metal contacts directly contact the second bonding metal contacts;
thinning down the substrate from a backside to expose the transistor devices in the device layer; and
forming a backside interconnect structure on a backside of the transistor devices.

18. The method of claim 17, further comprising:
forming second transistor devices in the device layer, each of the second transistor devices having a second channel region between second source/drain (S/D) regions and a second gate stack over the second channel region,
wherein the forming of the backside interconnect structure includes forming backside metal features electrically connected to the second source/drain (S/D) regions,
wherein the second S/D region is electrically connected to the one of the gate stacks.

19. The method of claim 17, wherein the forming of the carrier wafer structure includes:
forming the second bonding oxide over the carrier substrate;
patterning the second bonding oxide to form trenches exposing the carrier substrate; and
forming the second bonding metal contacts in the trenches.

20. The method of claim 17, further comprising:
forming gate vias over the gate stacks of the transistor devices;
forming first metal electrodes landing on the first doped regions;
forming second metal electrodes landing on the second doped regions;
forming first PN junction vias landing on the first metal electrodes; and
forming second PN junction vias landing on the second metal electrodes, wherein forming the frontside interconnect structure includes forming a bottom metal line of the gate path metal lines landing on the gate vias and the first PN junction vias and a bottom metal line of the thermal path metal lines landing on the second PN junction vias, wherein top surfaces of the bottom metal lines of the gate path metal lines and the thermal path metal lines are substantially coplanar.
